(19) United States
(12) Patent Application Publication
(10) Pub. No.: US 2023/0253428 A1
(43) Pub. Date: Aug. 10, 2023

(54) SENSOR DEVICE

(71) Applicant: SONY SEMICONDUCTOR SOLUTIONS CORPORATION, Kanagawa (JP)

(72) Inventor: Masao KANDA, Kanagawa (JP)

(73) Assignee: SONY SEMICONDUCTOR SOLUTIONS CORPORATION, Kanagawa (JP)

(21) Appl. No.: 18/002,934

(22) PCT Filed: Jun. 17, 2021
(86) PCT No.: PCT/JP2021/023055

§ 371 Date: Dec. 22, 2022

(30) Foreign Application Priority Data
Jul. 8, 2020 (JP) 2020-117680

(51) Int. Cl. H01L 27/146

(52) U.S. Cl. CPC H01L 27/1463; H01L 27/14603

(57) ABSTRACT

A sensor device according to the present technique includes an array of a plurality of pixels in the row direction and the column direction, each of the pixels including a photoelectric conversion element, wherein at least two kinds of pixels are disposed with an inter-pixel isolating structure or an inter-pixel light-shielding structure formed with a different pattern in one of the row direction and the column direction.

### TECHNICAL FIELD

The present technique relates to a sensor device including an array of pixels in the row direction and the column direction, the pixel including a photoelectric conversion element, and the present technique particularly relates to a technique for suppressing a flare (reflection diffraction ghost) caused by the periodicity of a microstructure pattern.

### BACKGROUND ART

A sensor device including an array of pixels, each of which includes a photoelectric conversion element, in the row direction and the column direction is widely known. Such sensor devices include a CCD (Charge Coupled Device) image sensor and a CMOS (Complementary Metal Oxide Semiconductor) image sensor.

Such a sensor device has a reflection surface with a fine periodic structure. The reflection surface may obtain the same effect as a reflection grating. If reflected light is generated by the reflection surface so as to be periodically increased and reduced in intensity, is reflected by another optical member, and enters the sensor device again, a flare may occur. Such a flare is also called a reflection diffraction ghost, which means a phenomenon of a ghost image with polka dots in a captured image.

PTL 1 discloses a technique for suppressing a flare by reducing periodicity with microlenses having different heights among pixels.

### CITATION LIST

### Patent Literature

[PTL 1]

JP 2017-92381 A

### SUMMARY

### Technical Problem

However, in order to obtain microlenses having different heights among pixels, the manufacturing process may be complicated, for example, an additional manufacturing step may be necessary.

The present technique has been devised in view of such circumstances. An object of the present technique is to suppress a flare while preventing the manufacturing process of a sensor device from becoming complicated.

### Solution to Problem

A first sensor device according to the present technique includes an array of a plurality of pixels in the row direction and the column direction, each of the pixels including a photoelectric conversion element, wherein at least two kinds of pixels are disposed with an inter-pixel isolating structure formed with a different pattern in one of the row direction and the column direction.

Thus, when a flare is suppressed by partially reducing the periodicity of the pattern of a fine structure, the need for an additional manufacturing step can be eliminated.

In the first sensor device according to the present technique, the at least two kinds of pixels may have different width patterns on the end face of the inter-pixel isolating structure near a light entrance surface.

The width of the inter-pixel isolating structure can be easily set by setting a mask pattern when the inter-pixel isolating structure is formed.

In the first sensor device according to the present technique, the end face of the inter-pixel isolating structure may have an equal area in the at least two kinds of pixels.

Thus, for the at least two kinds of pixels with the inter-pixel isolating structure formed with different patterns, an equal amount of incident light can be obtained in each of the pixels.

In the first sensor device according to the present technique, the inter-pixel isolating structure in each of the at least two kinds of pixels may have, as a width on the end face, a first width portion having a first width and a second width portion having a second width larger than the first width, and the total length of the second width portions in the inter-pixel isolating structure may be equal in the at least two kinds of pixels.

Thus, for the at least two kinds of pixels, when the inter-pixel isolating structure has an equal end face area near the light entrance surface to obtain an equal amount of incident light in each of the pixels, at least two widths can be combined as a width pattern of the inter-pixel isolating structure, thereby eliminating the need for a complicated change of the width.

A second sensor device according to the present technique includes an array of a plurality of pixels in the row direction and the column direction, each of the pixels including a photoelectric conversion element, wherein at least two kinds of pixels are disposed with an inter-pixel light-shielding structure formed with a different pattern in one of the row direction and the column direction.

Thus, when a flare is suppressed by partially reducing the periodicity of the pattern of a fine structure, the need for an additional manufacturing step can be eliminated.

In the second sensor device according to the present technique, the at least two kinds of pixels may have different width patterns on the end face of the inter-pixel light-shielding structure near the light entrance surface.

The width of the inter-pixel light-shielding structure can be easily set by setting a mask pattern when the inter-pixel light-shielding structure is formed.

In the second sensor device according to the present technique, the end face of the inter-pixel light-shielding structure may have an equal area in the at least two kinds of pixels.

Thus, for the at least two kinds of pixels with the inter-pixel light-shielding structure formed with different patterns, an equal amount of incident light can be obtained in each of the pixels.

In the second sensor device according to the present technique, the inter-pixel light-shielding structure in each of the at least two kinds of pixels may have, as a width on the end face, a first width portion having a first width and a second width portion having a second width larger than the first width, and the total length of the second width portions in the inter-pixel light-shielding structure may be equal in the at least two kinds of pixels.

Thus, for the at least two kinds of pixels, when the inter-pixel light-shielding structure has an equal end face area near the light entrance surface to obtain an equal amount of incident light in each of the pixels, at least two widths can be combined as a width pattern of the inter-pixel light-shielding structure, thereby eliminating the need for a complicated change of the width.

In the first or second sensor device according to the present technique, the at least two kinds of pixels may be disposed with the intra-pixel isolating structure formed with a different pattern in one of the row direction and the column direction.

The intra-pixel isolating structure formed with a different pattern can partially reduce the periodicity of the pattern of a fine structure. Furthermore, when the intra-pixel isolating structure is formed with a different pattern, the need for an additional manufacturing step can be eliminated.

In the first or second sensor device according to the present technique, the at least two kinds of pixels with the intra-pixel isolating structure formed with different patterns may have different width patterns on the end face of the intra-pixel isolating structure near the light entrance surface.

The width of the intra-pixel isolating structure can be easily set by setting a mask pattern when the intra-pixel isolating structure is formed.

The first or second sensor device according to the present technique may include a wiring layer stacked on a semiconductor substrate in which the photoelectric conversion elements are formed, wherein the at least two kinds of pixels are disposed with polysilicon portions that are formed in the wiring layer and located at different positions in the pixels in one of the row direction and the column direction.

The polysilicon portions formed in the wiring layer are located at different positions in the pixels, so that the periodicity of the pattern of the fine structure can be partially reduced. Furthermore, when the polysilicon portions are located at different positions in the pixels, the need for an additional manufacturing step can be eliminated.

The first or second sensor device according to the present technique may include the wiring layer stacked on the semiconductor substrate in which the photoelectric conversion elements are formed, wherein at least two kinds of pixels are disposed with intra-pixel wirings that are formed in the wiring layer and located at different positions in the pixels in one of the row direction and the column direction.

The intra-pixel wirings are located at different positions in the pixels, so that the periodicity of the pattern of the fine structure can be partially reduced. Furthermore, when the intra-pixel wirings are located at different positions in the pixels, the need for an additional manufacturing step can be eliminated.

The first or second sensor device according to the present technique may include inter-pixel wirings formed to extend in one of the column direction and the row direction and cross the plurality of pixels disposed in the one direction, the inter-pixel wirings being disposed for each of the pixels in the other direction of the column direction and the row direction, wherein the at least two kinds of pixels are disposed with the inter-pixel wirings formed with different patterns in the other direction.

The inter-pixel wirings disposed for each of the pixels are formed with different patterns, thereby partially reducing the periodicity of the pattern of the fine structure. Furthermore, when the inter-pixel wirings are formed with different patterns, the need for an additional manufacturing step can be eliminated.

In the first or second sensor device according to the present technique, the at least two kinds of pixels may have the inter-pixel wirings formed with different patterns such that the patterns of the inter-pixel wirings vary in width or interval.

The widths and intervals of the inter-pixel wirings can be easily set by setting a mask pattern when the inter-pixel wirings are formed.

In the first or second sensor device according to the present technique, the at least two kinds of pixels are disposed with different orientations in a pixel array plane in one of the row direction and the column direction.

The pixel array plane means a plane having an array of the pixels and corresponds to an X-Y plane when the row direction is the X direction and the column direction is the Y direction.

The pixels disposed with different orientations in the pixel array plane can partially reduce the periodicity of the pattern of the fine structure. Furthermore, when the pixels are disposed with different orientations, the need for an additional manufacturing step can be eliminated.

### BRIEF DESCRIPTION OF DRAWINGS

FIG. 1 is a block diagram illustrating a circuit configuration example of a sensor device as a first embodiment according to the present technique.

FIG. 2 is an equivalent circuit diagram of a pixel of the sensor device according to the embodiment.

FIG. 3 is a cross-sectional view for explaining a schematic structure of a pixel array part 3 according to the embodiment.

FIG. 4 is a plan view for explaining a schematic structure of an inter-pixel isolating structure and an inter-pixel light-shielding structure according to the embodiment.

FIG. 5 is an explanatory drawing of the principle of flare generation.

FIG. 6 is a plan view for explaining an example in which the total length of second width portions in each of the pixels is adjusted to the length of one side of the pixel, from among structural examples for suppressing a flare as a first embodiment.

FIG. 7 is a plan view for explaining another example in which the total length of the second width portions in each of the pixels is adjusted to the length of one side of the pixel, from among structural examples for suppressing a flare as the first embodiment.

FIG. 8 is a plan view for explaining another example in which the total length of the second width portions in each of the pixels is adjusted to the length of one side of the pixel, from among structural examples for suppressing a flare as the first embodiment.

FIG. 9 is a plan view for explaining still another example in which the total length of the second width portions in each of the pixels is adjusted to the length of one side of the pixel, from among structural examples for suppressing a flare as the first embodiment.

FIG. 10 is a plan view for explaining an example in which the total length of the second width portions in each of the pixels is adjusted to the length of two sides of the pixel, from among structural examples for suppressing a flare as the first embodiment.

FIG. 11 is a plan view for explaining another example in which the total length of the second width portions in each of the pixels is adjusted to the length of two sides of the pixel, from among structural examples for suppressing a flare as the first embodiment.

FIG. 12 is a plan view for explaining another example in which the total length of the second width portions in each of the pixels is adjusted to the length of two sides of the pixel, from among structural examples for suppressing a flare as the first embodiment.

FIG. 13 is a plan view for explaining still another example in which the total length of the second width portions in each of the pixels is adjusted to the length of two sides of the pixel, from among structural examples for suppressing a flare as the first embodiment.

FIG. 14 is a plan view for explaining an example in which the total length of the second width portions in each of the pixels is adjusted to the length of three sides of the pixel, from among structural examples for suppressing a flare as the first embodiment.

FIG. 15 is a plan view for explaining another example in which the total length of the second width portions in each of the pixels is adjusted to the length of three sides of the pixel, from among structural examples for suppressing a flare as the first embodiment.

FIG. 16 is a plan view for explaining another example in which the total length of the second width portions in each of the pixels is adjusted to the length of three sides of the pixel, from among structural examples for suppressing a flare as the first embodiment.

FIG. 17 is a plan view for explaining still another example in which the total length of the second width portions in each of the pixels is adjusted to the length of three sides of the pixel, from among structural examples for suppressing a flare as the first embodiment.

FIG. 18 is a plan view for explaining an example in which three or more widths are combined, from among structural examples for suppressing a flare as the first embodiment.

FIG. 19 is a plan view illustrating an example of the layout of intra-pixel isolating portions in the pixels in plan view.

FIG. 20 is a plan view for explaining a structural example for suppressing a flare as a second embodiment.

FIG. 21 is a plan view for explaining another structural example for suppressing a flare as the second embodiment.

FIG. 22 is a plan view illustrating an example of the layout of polysilicon portions in the pixels in plan view.

FIG. 23 is a plan view for explaining a structural example for suppressing a flare as a third embodiment.

FIG. 24 is a plan view for explaining another structural example for suppressing a flare as the third embodiment.

FIG. 25 is a plan view illustrating an example of the layout of intra-pixel wirings in the pixels in plan view.

FIG. 26 is a plan view for explaining a structural example for suppressing a flare as a fourth embodiment.

FIG. 27 is a plan view for explaining another structural example for suppressing a flare as the fourth embodiment.

FIG. 28 is a plan view for explaining inter-pixel wirings.

FIG. 29 is a plan view for explaining an example in which the patterns of the inter-pixel wirings vary in width, from among structural examples for suppressing a flare as a fifth embodiment.

FIG. 30 is a plan view for explaining an example in which the patterns of the inter-pixel wirings vary in interval, from among structural examples for suppressing a flare as the fifth embodiment.

FIG. 31 is a plan view for explaining a structural example for suppressing a flare as the fifth embodiment.

FIG. 32 is a plan view for explaining another structural example for suppressing a flare as the fifth embodiment.

FIG. 33 is a plan view for explaining another structural example for suppressing a flare as the fifth embodiment.

FIG. 34 is a plan view for explaining still another structural example for suppressing a flare as the fifth embodiment.

### DESCRIPTION OF EMBODIMENTS

Hereinafter, embodiments according to the present technique will be described in the following order with reference to the accompanying drawings.

<1. First embodiment>

[1-1. Circuit configuration of sensor device]

[1-2. Circuit configuration of pixel]

[1-3. Structure of pixel array part]

[1-4. Structure of pixel array part as first embodiment]

<2. Second embodiment>

<3. Third embodiment>

<4. Fourth embodiment>

<5. Fifth embodiment>

<6. Sixth embodiment>

<7. Modification example>

<8. Summary of embodiments>

<9. Present technique>

### 1. First Embodiment

### 1-1. Circuit Configuration of Sensor Device

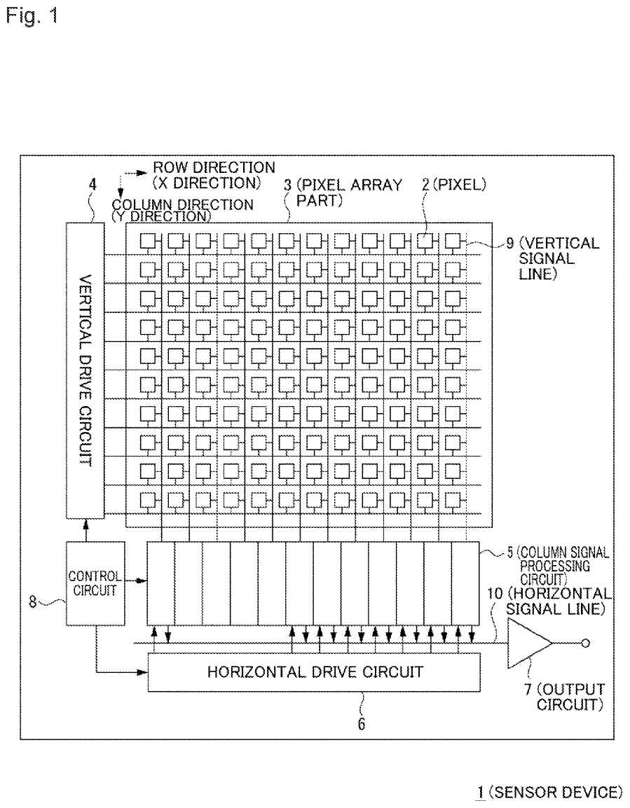

FIG. 1 is a block diagram illustrating a circuit configuration example of a sensor device 1 as a first embodiment according to the present technique.

The sensor device 1 includes a pixel array part 3 in which a plurality of pixels 2 are formed, a vertical drive circuit 4, column signal processing circuits 5, a horizontal drive circuit 6, an output circuit 7, and a control circuit 8.

The pixel 2 includes a photoelectric conversion element and a plurality of pixel transistors.

The circuit configuration of the pixel 2 will be described later.

The pixel array part 3 includes an array of the pixels 2 in the row direction and the column direction. Hereinafter, the row direction may be referred to as “X direction” and the column direction may be referred to as “Y direction”.

The pixel array part 3 includes an effective pixel region in which light is actually received and signal charges generated by photoelectric conversion are amplified to be read by the column signal processing circuits 5, and a black reference pixel region (not illustrated) for outputting optical black that serves as a reference for a black level. The black reference pixel region is typically formed on the outer peripheral part of the effective pixel region.

The control circuit 8 generates, for example, operation clocks and control signals for the vertical drive circuit 4, the column signal processing circuits 5, and the horizontal drive circuit 6 based on a vertical synchronizing signal, a horizontal synchronizing signal, and a master clock and outputs the operation clocks and the control signals to the vertical drive circuit 4, the column signal processing circuits 5, and the horizontal drive circuit 6.

The vertical drive circuit 4 is composed of, for example, shift registers and sequentially and vertically selects and scans the pixels 2 of the pixel array part 3 in rows. A pixel signal based on a signal charge obtained in the pixel 2 according to the amount of received light is outputted to the column signal processing circuit 5 through a vertical signal line 9.

The column signal processing circuits 5 are disposed, for example, for the respective columns of the pixels 2 and perform noise reduction or signal processing such as signal amplification on signals outputted from the pixels 2 of one row, on the basis of a signal from the black reference pixel region (not illustrated, but formed around the effective pixel region) for each pixel column. At the output stage of the column signal processing circuit 5, a horizontal selection switch (not illustrated) is provided between the output stage and a horizontal signal line 10.

The horizontal drive circuit 6 is composed of, for example, shift registers. The horizontal drive circuit 6 sequentially outputs horizontal scanning pulses to sequentially select the column signal processing circuits 5 and causes the column signal processing circuits 5 to output pixel signals to the horizontal signal line 10.

The output circuit 7 performs signal processing on the signals sequentially supplied from the column signal processing circuits 5 through the horizontal signal line 10 and then outputs the signals.

### 1-2. Circuit Configuration of Pixel

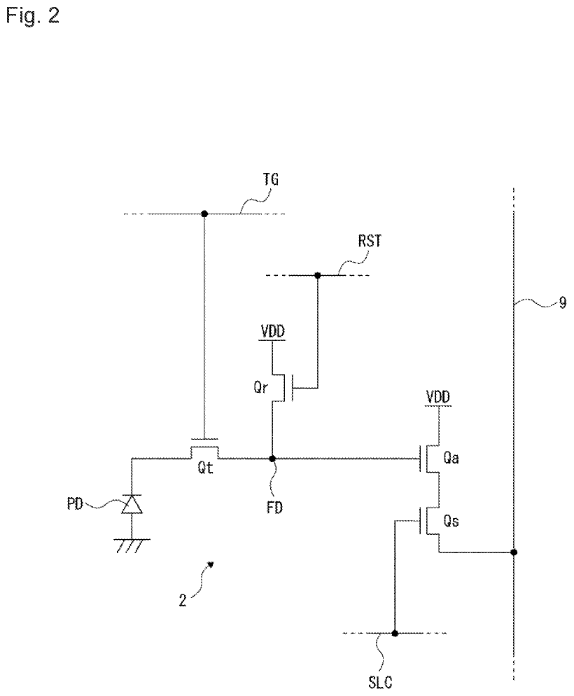

FIG. 2 is an equivalent circuit diagram of the pixel 2.

As illustrated in FIG. 2, the pixel 2 includes a photodiode PD as a photoelectric conversion element, a transfer transistor Qt, a floating diffusion (floating diffusion region) FD, a reset transistor Qr, an amplifying transistor Qa, and a selecting transistor Qs.

In the present example, the transistors in the pixel 2 include, for example, a MOSFET (metal-oxide-semiconductor field-effect transistor).

The transfer transistor Qt has the gate connected to the supply line of a transfer driving signal TG. When the transfer driving signal TG is turned on, the transfer transistor Qt is brought into conduction to transfer a signal charge stored in the photodiode PD to the floating diffusion FD.

The floating diffusion FD is a charge holding part that temporarily holds a charge transferred from the photodiode PD.

The reset transistor Qr has the gate connected to the supply line of a reset signal RST. When the reset signal RST is turned on, the reset transistor Qr is brought into conduction to reset the potential of the floating diffusion FD to a reference potential VDD.

The amplifying transistor Qa has the source connected to the vertical signal line 9 via the selecting transistor Qs and the drain connected to the reference potential VDD (constant current source), constituting a source follower circuit.

The selecting transistor Qs is connected between the source of the amplifying transistor Qa and the vertical signal line 9 and has the gate connected to the supply line of a selecting signal SLC. When the selecting signal SLC is turned on, the selecting transistor Qs is brought into conduction to output the charge held in the floating diffusion FD to the vertical signal line 9 via the amplifying transistor Qa.

In this configuration, the transfer driving signal TG, the reset signal RST, and the selecting signal SLC are outputted by the vertical drive circuit 4 illustrated in FIG. 1.

The operations of the pixel 2 in the configuration will be simply described below. First, before the start of light reception, a charge resetting operation (electronic shutter operation) for resetting the charge of the pixel 2 is performed. Specifically, the reset transistor Qr and the transfer transistor Qt are turned on (conduction state) to reset the accumulated charges of the photodiode PD and the floating diffusion FD.

After the accumulated charges are reset, the reset transistor Qr and the transfer transistor Qt are turned off to start charge accumulation in the photodiode PD. Thereafter, when a charge signal accumulated in the photodiode PD is read, the transfer transistor Qt is turned on and the selecting transistor Qs is turned on. Thus, the charge signal is transferred from the photodiode PD to the floating diffusion FD, and a charge signal held in the floating diffusion FD is outputted to the vertical signal line 9 via the amplifying transistor Qa.

### 1-3. Structure of Pixel Array Part

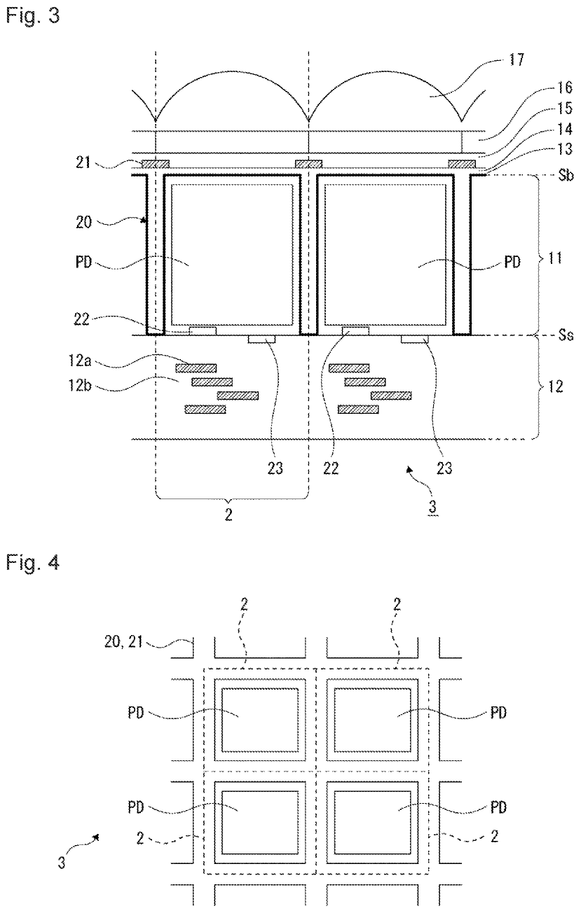

FIG. 3 is an explanatory cross-sectional view illustrating a schematic structure of the pixel array part 3.

The sensor device 1 of the present embodiment is configured as a backside illuminated CMOS (Complementary Metal Oxide Semiconductor) solid-state image sensor. In this case, “backside” is defined with reference to a frontside Ss and a backside Sb of a semiconductor substrate 11 included in the pixel array part 3.

As illustrated in FIG. 3, the pixel array part 3 includes the semiconductor substrate 11 and a wiring layer 12 formed on the frontside Ss of the semiconductor substrate 11. On the backside Sb of the semiconductor substrate 11, a fixed charge film 13 is formed as an insulating film having a fixed charge, and an insulating film 14 is formed on the fixed charge film 13. Moreover, an inter-pixel light-shielding portion 21, a flattening film 15, a filter layer 16, and microlenses (on-chip lenses) 17 are formed in this order on the insulating film 14.

The pixel transistors (the transfer transistor Qt, the reset transistor Qr, the amplifying transistor Qa, the selecting transistor Qs) formed on each of the pixels 2 are not illustrated in FIG. 3. In this configuration, conductors acting as the electrodes (gate, drain, and source electrodes) of the pixel transistors are formed near the frontside Ss of the semiconductor substrate 11 in the wiring layer 12.

The semiconductor substrate 11 is made of, for example, silicon (Si) and is formed with a thickness of, for example, about 1 μm to 6 μm. In the semiconductor substrate 11, the photodiode PD serving as a photoelectric conversion element is formed in the region of the pixel 2. The adjacent photodiodes PD are electrically isolated from each other by an inter-pixel isolating portion 20.

The inter-pixel isolating portion 20 includes a part of the fixed charge film 13 and a part of the insulating film 14. As illustrated in the plan view of FIG. 4, the inter-pixel isolating portion 20 is formed with a grid-like pattern surrounding the photodiodes PD of the pixels 2. With this configuration, the inter-pixel isolating portion 20 has the function of electrically isolating the pixels 2 so as to prevent leakage of signal charge between the pixels 2.

The inter-pixel isolating portion 20 can be formed by forming the fixed charge film 13 and the insulating film 14 in a trench (groove) surrounding the formation region of the photodiode PD in the semiconductor substrate 11 (so-called trench isolation). Specifically, the inter-pixel isolating portion 20 can be configured as, for example, FDTI (Front Deep Trench Isolation), FFTI (Front Full Trench Isolation), RDTI (Reversed Deep Trench Isolation), or RFTI (Reversed Full Trench Isolation).

In this case, “front” and “reversed” mean a difference between the frontside Ss and the backside Sb of the semiconductor substrate 11 when cutting for forming a trench is performed from the frontside Ss or the backside Sb. Moreover, “deep” and “full” mean a depth of the trench (groove depth). “Full” means penetration through the semiconductor substrate 11, whereas “deep” means the formation of a trench to a depth without penetrating the semiconductor substrate 11.

FIG. 3 illustrates a structure for RDTI or RFTI, in which the trench is formed from the backside Sb.

In this structure, the trench formed in the semiconductor substrate 11 tends to gradually decrease in width in the direction of cutting. Thus, in the case of a trench formed from the frontside Ss as in FDTI and FFTI, the inter-pixel isolating portion 20 has the characteristic of being smaller in width on the backside Sb than on the frontside Ss. In contrast, in the case of a trench formed from the backside Sb as in RDTI and RFTI, the inter-pixel isolating portion 20 has the characteristic of being smaller in width on the frontside Sb than on the backside Ss.

In the step of forming the inter-pixel isolating portion 20, the fixed charge film 13 is formed on the side wall surface and bottom of the trench and is formed over the backside Sb of the semiconductor substrate 11. The fixed charge film 13 is preferably made of a material that can enhance pinning by generating a fixed charge when being stacked on the substrate made of, for example, silicon. The fixed charge film 13 can be a high-refractive-index material film having a negative charge or a high-dielectric film. As a specific material, for example, an oxide or a nitride that contains at least one element of hafnium (Hf), aluminum (Al), zirconium (Zr), tantalum (Ta), and titanium (Ti) may be used. As a deposition method, for example, CVD (Chemical Vapor Deposition), sputtering, or ALD (Atomic Layer Deposition) may be used. According to ALD, a SiO₂ (silicon oxide) film that reduces an interface state during the film formation can be simultaneously formed with a thickness of about 1 nm. The fixed charge film 13 may additionally contain silicon or nitrogen (N) as a material without interfering with insulation. The concentration of the material is properly determined without interfering with the insulation of the film. The addition of silicon or nitrogen (N) can improve the heat resistance of the film and the capability of blocking ion implantation during the process.

In the present embodiment, the fixed charge film 13 having a negative charge is formed in the inter-pixel isolating portion 20 and on the backside Sb of the semiconductor substrate 11, and thus an inversion layer is formed on a surface in contact with the fixed charge film 13. This causes a silicon interface to be pinned with the inversion layer, thereby suppressing the generation of a dark current. If a trench for forming the inter-pixel isolating portion 20 is formed on the semiconductor substrate 11, physical damage may occur on the side wall and bottom of the trench and eliminate pinning around the trench. To address the problem, in the present embodiment, the fixed charge film 13 having a large amount of fixed charge is formed on the side wall surface and bottom of the trench, thereby preventing pinning from being eliminated.

The insulating film 14 is embedded in the trench in which the fixed charge film 13 is formed, and is formed over the backside Sb of the semiconductor substrate 11. The insulating film 14 is preferably made of a material having a different refractive index from the fixed charge film 13. For example, silicon oxide, silicon nitride, silicon oxynitride, and resin can be used. Furthermore, a material with a property of having no positive fixed charge or having a small amount of positive fixed charge can be used for the insulating film 14.

In the present embodiment, the insulating film 14 is embedded in the inter-pixel isolating portion 20, so that the photodiodes PD are isolated from each other by the insulating film 14 between the pixels 2. This hardly causes leakage of signal charge between the adjacent pixels, thereby suppressing leakage of signal charge to the adjacent photodiodes PD when the signal charge exceeds a saturation charge amount (Qs).

In the present embodiment, a two-layer structure of the fixed charge film 13 and the insulating film 14 on the backside Sb serving as the light entrance surface of the semiconductor substrate 11 also acts as an antireflection film because of a difference in refractive index between the fixed charge film 13 and the insulating film 14.

The inter-pixel light-shielding portion 21 is formed with a grid-like pattern, in which the photodiodes PD of the pixels 2 are opened, on the insulating film 14 formed on the backside Sb of the semiconductor substrate 11. In other words, as illustrated in the plan view of FIG. 4, the inter-pixel light-shielding portion 21 is formed at a position corresponding to the inter-pixel isolating portion 20.

The inter-pixel light-shielding portion 21 may be made of any light blocking material, for example, tungsten (W), aluminum (Al), or copper (Cu).

Between the adjacent pixels 2, the inter-pixel light-shielding portion 21 prevents light to be incident only on one of the pixels 2 from leaking to the other pixel 2.

The flattening film 15 is formed on the inter-pixel light-shielding portion 21 and on a portion where the inter-pixel light-shielding portion 21 is not formed in the insulating film 14. This flattens a surface on the backside Sb of the semiconductor substrate 11. The flattening film 15 can be made of, for example, an organic material such as resin.

The filter layer 16 is formed on the flattening film 15 and includes a wave filter that allows the passage of light of a predetermined waveband for each of the pixels 2. In this case, the wave filter may be, for example, a wave filter that allows the passage of R (red) light, G(green) light, or B(blue) light or a wave filter that allows the passage of infrared light.

The microlenses 17 for the respective pixels 2 are formed on the filter layer 16. The microlenses 17 condense incident light, and the condensed light efficiently enters the photodiodes PD through the wave filters in the filter layer 16.

The wiring layer 12 is formed on the frontside Ss of the semiconductor substrate 11 and is configured with wirings 12a stacked as a plurality of layers with an interlayer insulating film 12b interposed therebetween. The pixel transistors are driven through the wirings 12a formed in the wiring layer 12.

In the pixel array part 3 of the present embodiment, an intra-pixel isolating portion 22 is formed for each of the pixels 2. The intra-pixel isolating portion 22 has the function of dividing an active region in the semiconductor substrate 11 and is formed in the semiconductor substrate 11.

The intra-pixel isolating portion 22 can be configured as, for example, STI (Shallow Trench Isolation). The intra-pixel isolating portion 22 can be made of, for example, SiO₂.

Moreover, in the pixel array part 3 of the present example, a polysilicon portion 23 made of polysilicon is formed for each of the pixels 2. The polysilicon portion 23 is provided for reflecting, to the photodiode PD, light having passed through the photodiode PD without photoelectric conversion after entering the photodiode PD through the microlens 17. As illustrated in FIG. 3, the polysilicon portion 23 is formed in the wiring layer 12.

In the sensor device 1 including the pixel array part 3, light is emitted from the backside Sb of the semiconductor substrate 11, and light having passed through the microlens 17 and the filter layer 16 undergoes photoelectric conversion through the photodiode PD so as to generate a signal charge. Subsequently, a pixel signal based on the signal charge obtained by the photoelectric conversion passes through the pixel transistors formed on the frontside Ss of the semiconductor substrate 11 and is outputted through the vertical signal line 9 formed as the predetermined wiring 12a in the wiring layer 12.

### 1-4. Structure of Pixel Array Part as First Embodiment

The sensor device 1 configured thus can be regarded as a sensor device having a reflection surface with a fine periodic structure. The reflection surface may cause the same effect as a reflection grating. The same effect as such a reflection grating may lead to a flare. The flare is also called a reflection diffraction ghost, which means a phenomenon of a ghost image with polka dots in a captured image.

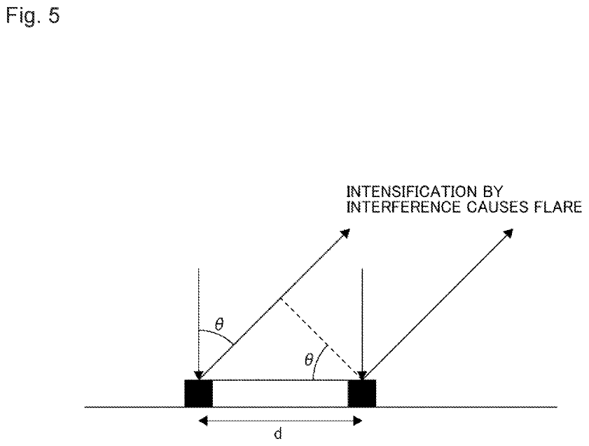

FIG. 5 is an explanatory drawing of the principle of flare generation.

“d” in FIG. 5 means the pitch of a fine structure (grating). According to the Bragg's rule, a condition for intensifying reflected light by interference is expressed as follows:

“sinθ=nλd”

where θ is a reflection angle of incident light, λ is a wavelength of incident light, and n is an integer equal to or larger than 0 (0, 1, 2, . . . ).

If the pixels 2 are completely identical in structure, the intervals d are constant and reflected light is intensified by interference at the same angle θ in the pixels 2, thereby generating a strong flare at the angle θ. For example, in the case of d=d₁ in the pixels 2, “sinθ₁=nλ/d₁” is determined, thereby generating a strong flare at a specific angle θ1.

Thus, in the pixel array part 3, at least some of the intervals d are changed from the other pitches d, that is, the periodicity of the pattern of the fine structure is partially reduced to change at least some of the angles θ for intensification by interference, so that a flare is suppressed.

For example, for the five consecutive pixels 2 disposed in the row direction, if the intervals d of the adjacent pixels 2 are varied to d₁₀, d₁₁, d₁₂, and d₁₃, the angle θ for intensification by interference can be varied to d₁₀, d₁₁, d₁₂, and d₁₃, thereby enhancing the effect of suppressing a flare.

In the present embodiment, the periodicity of the pattern of the fine structure is partially reduced, which means that at least two kinds of pixels 2 with different structure patterns are disposed in at least one of the row direction and the column direction.

The first embodiment describes an example in which at least two kinds of pixels 2 are disposed in the row direction and the column direction such that at least one of the inter-pixel isolating portion 20 and the inter-pixel light-shielding portion 21 is formed with a different pattern.

Specifically, in this example, at least one of the inter-pixel isolating portion 20 and the inter-pixel light-shielding portion 21 has a different width pattern. “Width” in this example means the width of a side portion in plan view. “Width” in this example means the width of an end face on the light entrance surface.

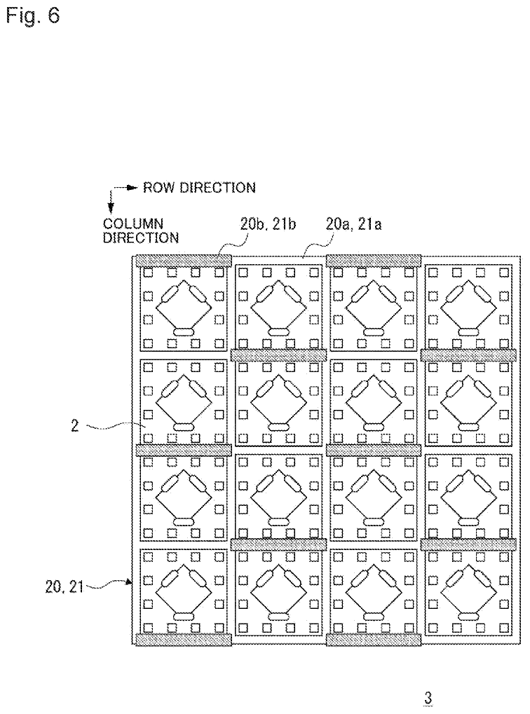

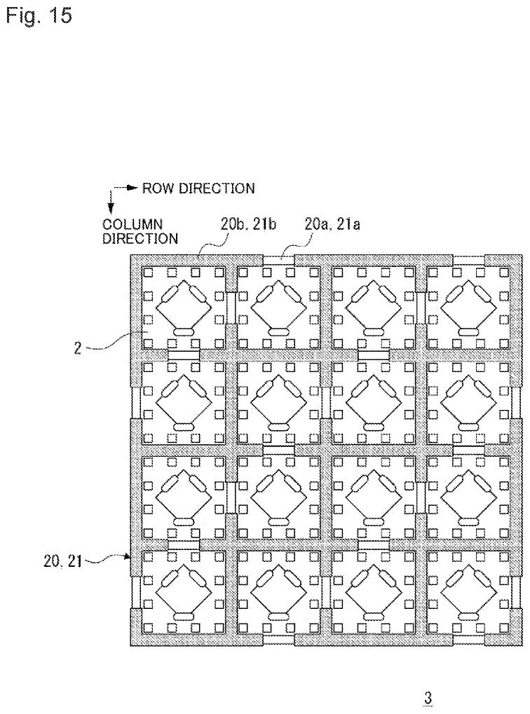

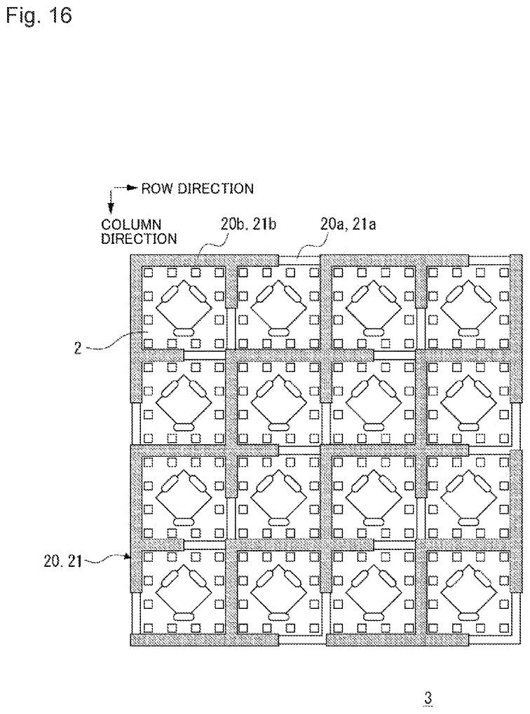

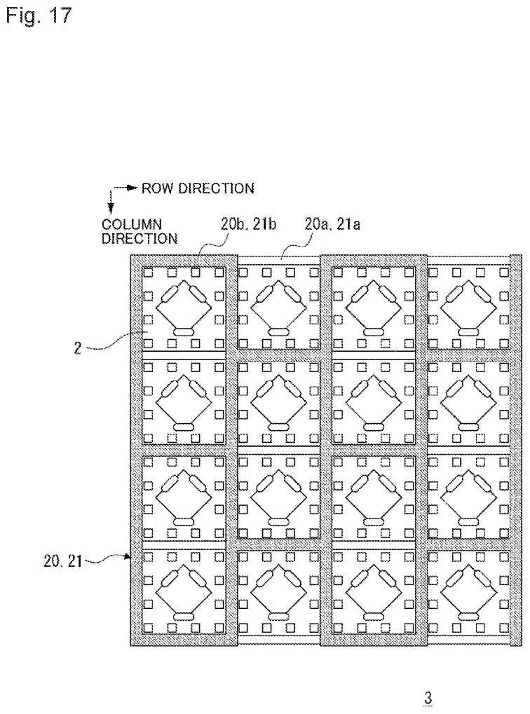

The plan views of FIGS. 6 to 17 illustrate examples of multiple kinds of pixels 2 disposed in the row direction and the column direction such that at least one of the inter-pixel isolating portion 20 and the inter-pixel light-shielding portion 21 is formed with a different width pattern.

In the examples of FIGS. 6 to 17, variations in width are combinations of two widths: a first width and a second width larger than the first width. In the following description, for the inter-pixel isolating portion 20 and the inter-pixel light-shielding portion 21, portions having the first width will be denoted as a first width portion 20a and a first width portion 21a and portions having the second width will be denoted as a second width portion 20b and a second width portion 21b.

In view of the suppression of a flare, reducing the periodicity of the width pattern is effective. However, the pixels 2 varying in end face area near the light entrance surface may cause irregularities in sensitivity for receiving light. Thus, in the present example, the pixels 2 are configured with an equal end face area near the light entrance surface while the inter-pixel isolating portion 20 and the inter-pixel light-shielding portion 21 have different width patterns.

Specifically, in the present example, the total length of the second width portions 20b and 21b is equal in the pixels 2, so that the pixels 2 have an equal area.

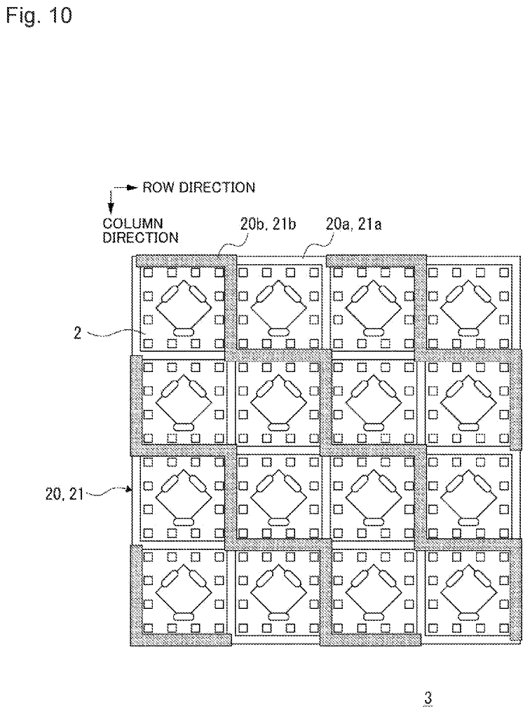

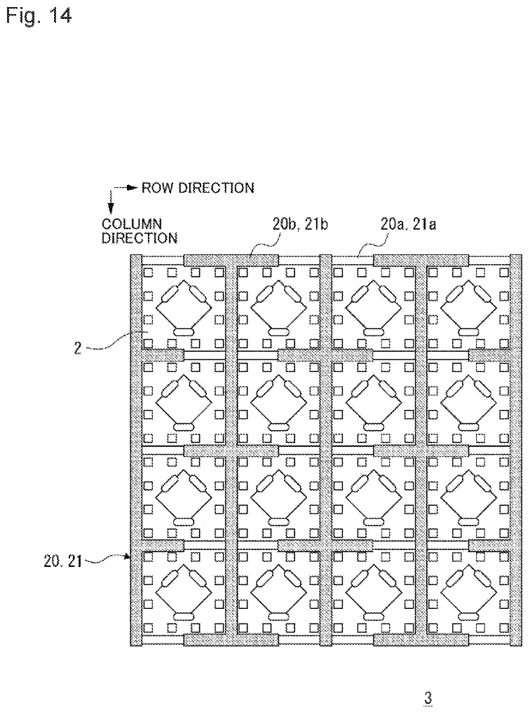

FIGS. 6 to 9 illustrate examples in which the total length of the second width portions 20b and 21b in each of the pixels 2 is adjusted to the length of one side of the pixel 2. FIGS. 10 to 13 illustrate examples in which the total length is adjusted to the length of two sides of the pixel 2. FIGS. 14 to 17 illustrate examples in which the total length is adjusted to the length of three sides of the pixel 2.

In FIGS. 6 to 9 (total length=one side), the example of FIG. 6 first illustrates the second width portions 20b and 21b disposed on one of the sides extending in the row direction in each of the pixels 2. Specifically, in the example of FIG. 6, the pixels 2 having the second width portions 20b and 21b on one of two sides extending in the row direction and the pixels 2 having the second width portions 20b and 21b on the other side are alternately disposed in the row direction and the column direction, so that two kinds of pixels 2 with the inter-pixel isolating portion 20 and the inter-pixel light-shielding portion 21 with different width patterns are alternately disposed in the row direction and the column direction.

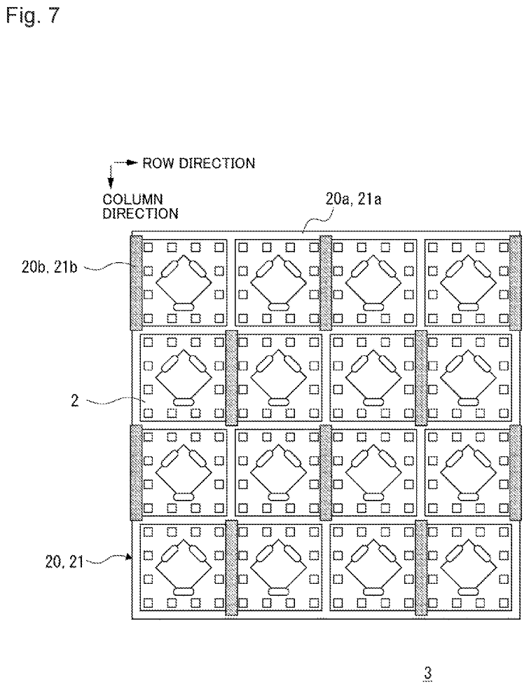

In the example of FIG. 7, the pixels 2 have the second width portions 20b and 21b on one side extending in the column direction. Specifically, the pixels 2 having the second width portions 20b and 21b on one of two sides extending in the column direction and the pixels 2 having the second width portions 20b and 21b on the other side are alternately disposed in the row direction and the column direction, so that two kinds of pixels 2 with the inter-pixel isolating portion 20 and the inter-pixel light-shielding portion 21 with different width patterns are alternately disposed in the row direction and the column direction.

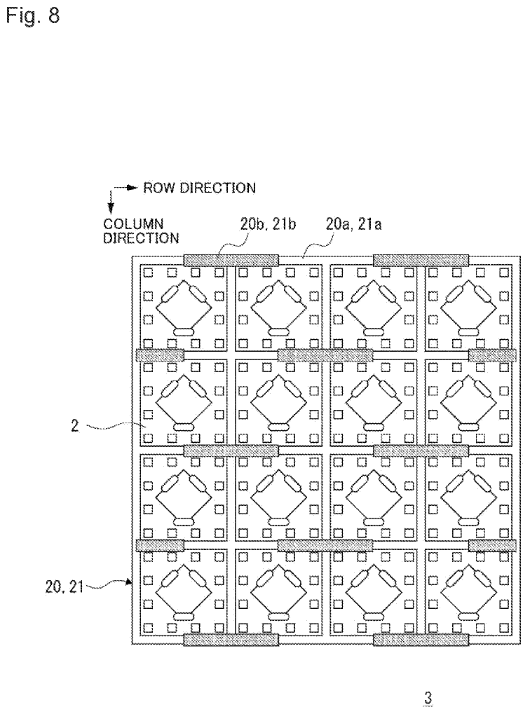

In FIG. 8, the formation positions of the second width portions 20b and 21b are shifted in the row direction by the half length of the pixel from those in the example of FIG. 6.

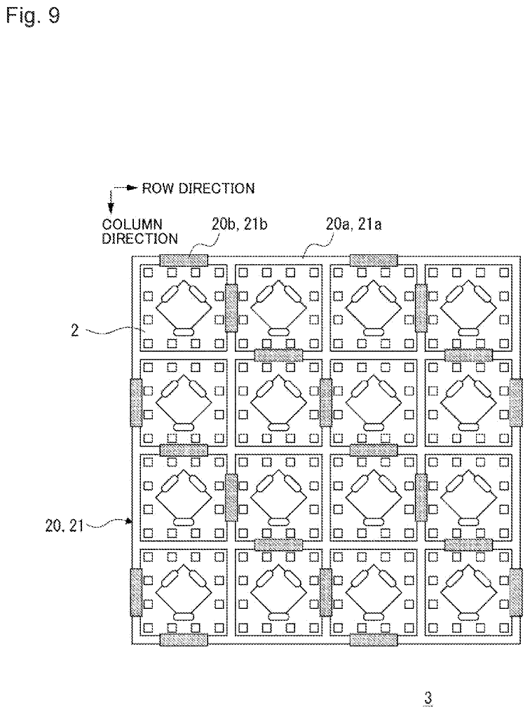

FIG. 9 illustrate an example in which the second width portions 20b and 21b as long as a half of the pixel are disposed on two different sides of each of the pixels 2. Specifically, in FIG. 9, the second width portions 20b and 21b as long as a half of the pixel are disposed on one side in the row direction and one side in the column direction in each of the pixels 2. As illustrated in FIG. 9, the second width portions 20b and 21b extending in the row direction and the second width portions 20b and 21b extending in the column direction are disposed in every other pixel in the row direction and the column direction, so that two kinds of pixels 2 with the inter-pixel isolating portion 20 and the inter-pixel light-shielding portion 21 with different width patterns are alternately disposed in the row direction and the column direction.

In FIGS. 10 to 13 (total length=two sides), FIG. 10 illustrates an example in which the second width portions 20b and 21b as long as one side of the pixel are disposed on two adjacent sides of each of the pixels 2. Specifically, in FIG. 10, when the four sides of the pixel 2 are denoted as a first side, a second side, a third side, and a fourth side in the clockwise direction, the pixels 2 having the second width portions 20b and 21b on the first side and the second side and the pixels 2 having the second width portions 20b and 21b on the third side and the fourth side are alternately disposed in the row direction and the column direction, so that two kinds of pixels 2 with the inter-pixel isolating portion 20 and the inter-pixel light-shielding portion 21 with different width patterns are alternately disposed in the row direction and the column direction.

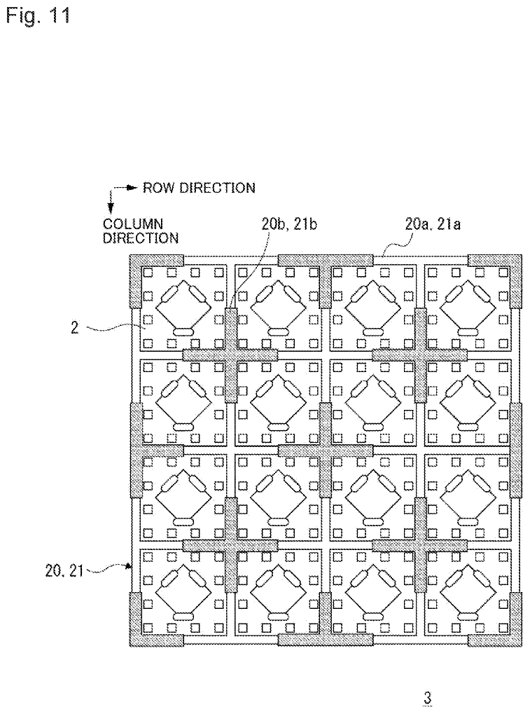

In the example of FIG. 11, the second width portions 20b and 21b are disposed at the intersections of the inter-pixel isolating portion 20 and the inter-pixel light-shielding portion 21. Specifically, the second width portions 20b and 21b are disposed at every other intersection in the row direction and the column direction.

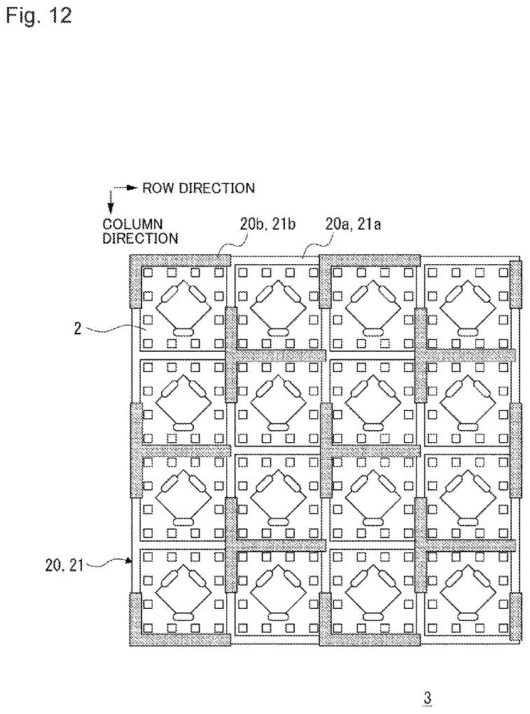

FIG. 12 illustrates an application example of the second width portions 20b and 21b shaped like a letter T. The second width portions 20b and 21b shape like a letter T are disposed at every other pixel in the row direction and the column direction.

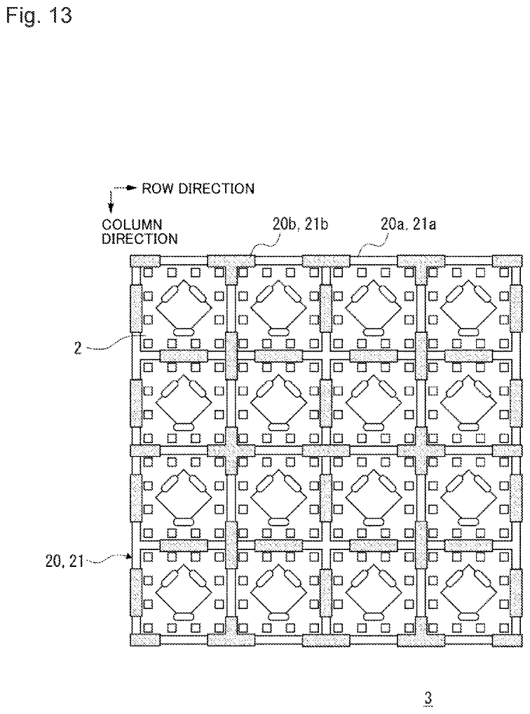

In FIG. 13, the second width portions 20b and 21b as long as a half of the pixel and the second width portions 20b and 21b with a crisscross pattern as long as a half of the pixel in the row direction and the column direction are disposed in a predetermined pattern, so that two kinds of pixels 2 with the inter-pixel isolating portion 20 and the inter-pixel light-shielding portion 21 with different width patterns are alternately disposed in the row direction and the column direction.

In FIGS. 14 to 17 (total length=three sides), two kinds of pixels 2 with the inter-pixel isolating portion 20 and the inter-pixel light-shielding portion 21 with different width patterns are alternately disposed in the row direction and the column direction on condition that the total length of the second width portions 20b and 21b in each of the pixels 2 is equal to the length of three sides of the pixel 2.

The example of the total length=three sides in FIGS. 14 to 17 is applicable to the example of the total length=one side when the locations of the first width portions 20a and 21a and the second width portions 20b and 21b are reversed.

In the foregoing example, two widths of the first width portions 20a and 21a and the second width portions 20b and 21b are combined as an example of the inter-pixel isolating portion 20 and the inter-pixel light-shielding portion 21 with different width patterns. Three or more widths can be combined instead.

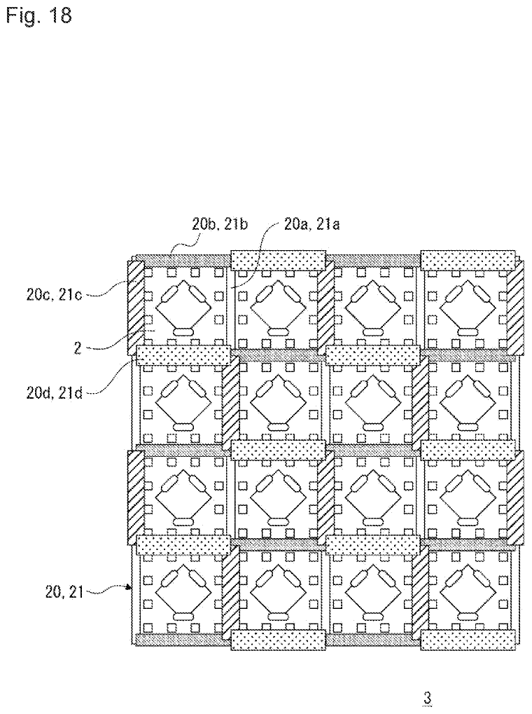

FIG. 18 illustrates an example of a combination of four widths.

In FIG. 18, portions having four different widths are denoted as the first width portions 20a and 21a, the second width portions 20b and 21b, third width portions 20c and 21c, and fourth width portions 20d and 21d. Specifically, the example of FIG. 18 satisfies three conditions:

Condition 1) The first width portions 20a and 21a, the second width portions 20b and 21b, the third width portions 20c and 21c, and the fourth width portions 20d and 21d are all disposed in each of the pixels 2.

Condition 2) The same width portions are disposed on sides at the borders between the adjacent pixels 2, from among the first width portions 20a and 21a, the second width portions 20b and 21b, the third width portions 20c and 21c, and the fourth width portions 20d and 21d.

Condition 3) Two kinds of pixels 2 are alternately disposed in the row direction and the column direction with the first width portions 20a and 21a, the second width portions 20b and 21b, the third width portions 20c and 21c, and the fourth width portions 20d and 21d disposed with different patterns.

Thus, the pixels 2 are configured with an equal end face area near the light entrance surface while reducing the periodicity of the width patterns of the inter-pixel isolating portion 20 and the inter-pixel light-shielding portion 21.

In the foregoing example, at least one of the inter-pixel isolating portion 20 and the inter-pixel light-shielding portion 21 has a different width pattern. Both of the inter-pixel isolating portion 20 and the inter-pixel light-shielding portion 21 can be varied in width pattern.

### 2. Second Embodiment

A second embodiment will be described below.

In the second embodiment, the formation pattern of intra-pixel isolating portions 22 is partially changed.

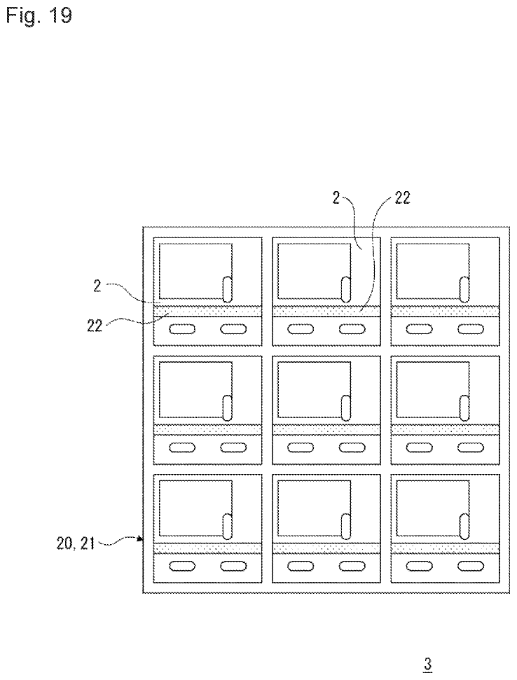

FIG. 19 is a plan view illustrating an example of the layout of intra-pixel isolating portions 22 in pixels 2 in plan view. As illustrated in FIG. 19, the intra-pixel isolating portions 22 is formed to divide the pixel 2 in plan view.

The intra-pixel isolating portions 22 are typically formed with a uniform pattern in the pixels 2 as illustrated in FIG. 19, exhibiting high periodicity.

Thus, in the second embodiment, the periodicity is reduced by partially changing the formation pattern of the intra-pixel isolating portions 22. Specifically, in the present example, at least two kinds of pixels 2 are disposed with the intra-pixel isolating portions 22 having different widths in one of the row direction and the column direction.

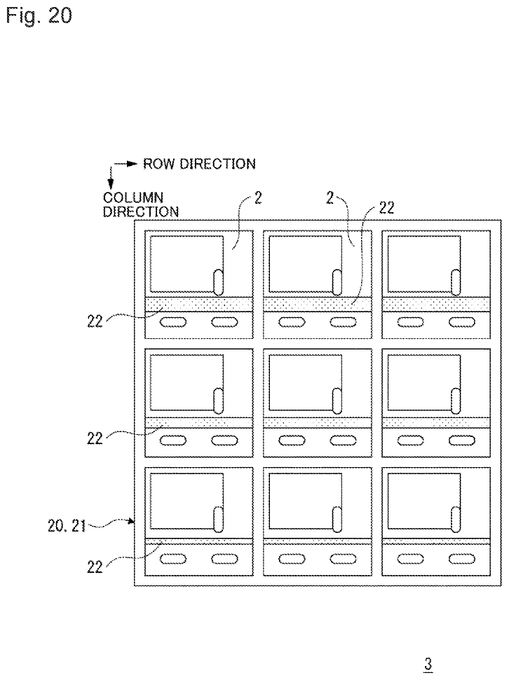

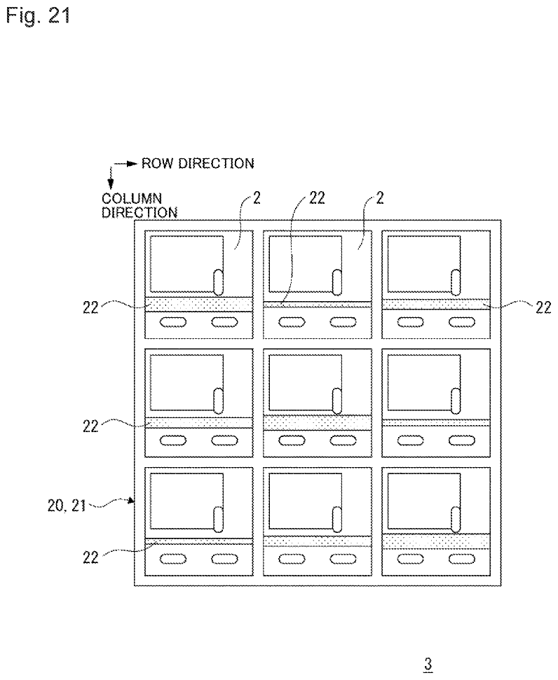

The plan views of FIGS. 20 and 21 illustrate specific examples of the second embodiment.

In the example of FIG. 20, three kinds of pixels 2 are disposed with the intra-pixel isolating portions 22 having different widths in the column direction. Specifically, three kinds of pixels 2 are disposed with the intra-pixel isolating portions 22 having “large”, “medium”, and “small” widths in the column direction.

In the example of FIG. 21, three kinds of pixels 2 are disposed with the intra-pixel isolating portions 22 having different widths in the row direction and the column direction.

Referring to FIG. 3, the intra-pixel isolating portions 22 are formed in a wiring layer 12 formed on a backside Sb (that is, the opposite side from a light entrance surface) of a semiconductor substrate 11 and hardly affect the amount of incident light on photodiodes PD. Thus, even if the area of the intra-pixel isolating portion 22 (an end face area near the light entrance surface) varies between the pixels 2, the intra-pixel isolating portions 22 hardly affect irregularities in sensitivity.

### 3. Third Embodiment

In a third embodiment, the layout of polysilicon portions 23 in pixels is partially changed.

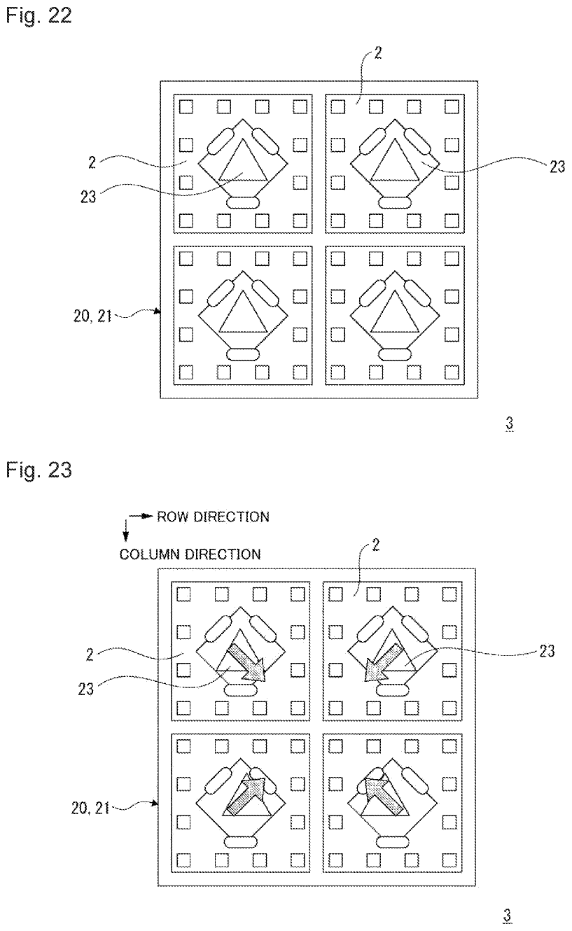

FIG. 22 is a plan view illustrating an example of the layout of the polysilicon portions 23 in pixels 2 in plan view.

The polysilicon portion 23 is typically disposed at the same position in each of the pixels 2, exhibiting high periodicity. Hereinafter, the same position in the pixel is denoted as “reference poly-position”.

In the third embodiment, the periodicity is reduced by partially changing the layout of the polysilicon portions 23 in the pixels. Specifically, at least two kinds of pixels 2 are disposed with the polysilicon portions 23 at different positions in the pixels in one of the row direction and the column direction.

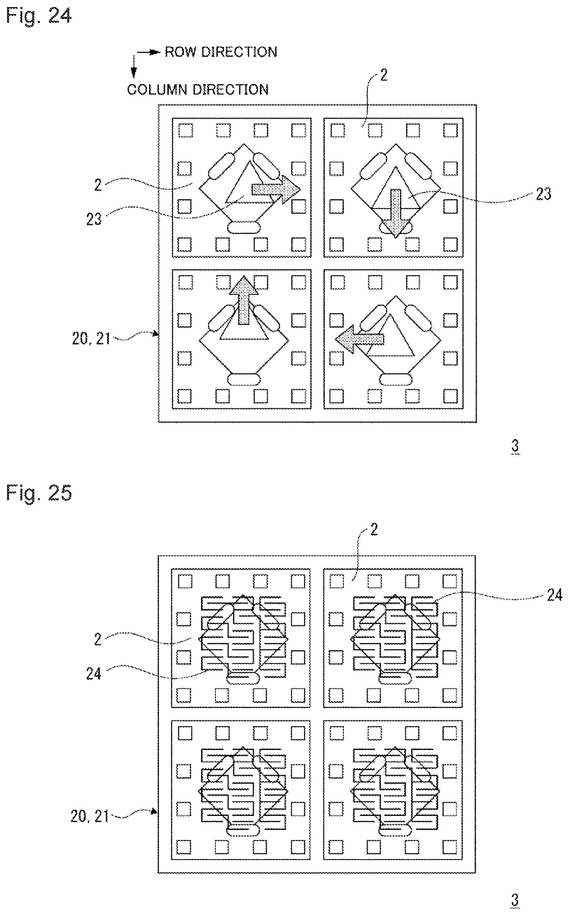

The plan views of FIGS. 23 and 24 illustrate specific examples of the third embodiment. In the examples of FIGS. 23 and 24, two kinds of pixels 2 are disposed with the polysilicon portions 23 at different positions in the pixels in the row direction and the column direction. FIG. 23 illustrates an example in which the positions of the polysilicon portions 23 in the pixels are diagonally shifted from the reference poly-position of FIG. 22. FIG. 24 illustrates an example in which the positions of the polysilicon portions 23 in the pixels are shifted from the reference poly-position in the row direction and the column direction.

Even if the position of the polysilicon portion 23 varies between the pixels 2, the reflectivity of the polysilicon portion 23 is not changed and thus influence on irregularities in sensitivity can be reduced.

### 4. Fourth Embodiment

In a fourth embodiment, the layout of intra-pixel wirings 24 in pixels is partially changed.

The plan view of FIG. 25 is an explanatory drawing of the intra-pixel wirings 24.

The intra-pixel wiring 24 is a wiring (metal wiring) formed in a wiring layer 12 of each pixel 2. The intra-pixel wiring 24 is typically disposed at the same position in each pixel 2, exhibiting high periodicity. Hereinafter, the same position of the intra-pixel wiring 24 in the pixel is denoted as “reference wiring position”.

In the fourth embodiment, the periodicity is reduced by partially changing the layout of the intra-pixel wirings 24 in the pixels. Specifically, at least two kinds of pixels 2 are disposed with the intra-pixel wirings 24 at different positions in the pixels in one of the row direction and the column direction.

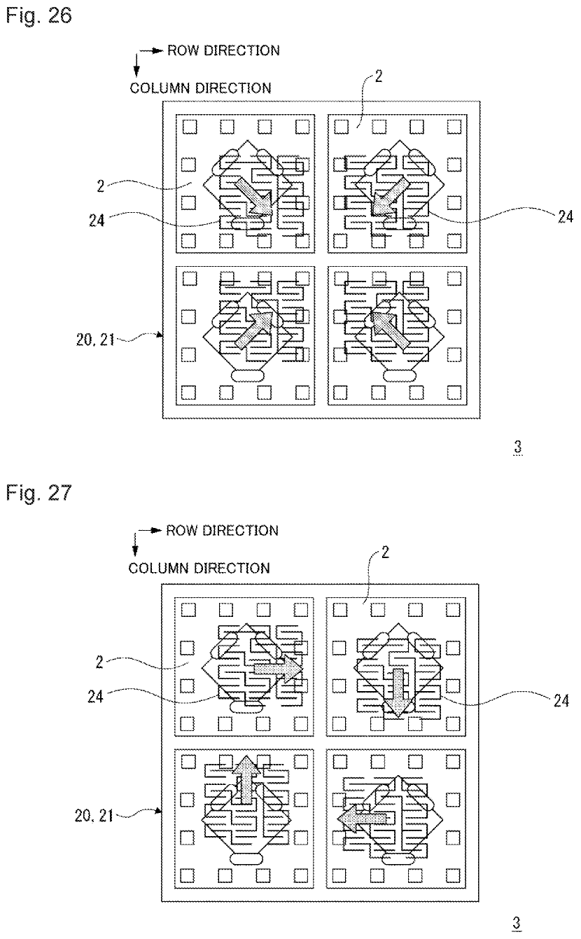

The plan views of FIGS. 26 and 27 illustrate specific examples of the fourth embodiment.

In the examples of FIGS. 26 and 27, two kinds of pixels 2 are disposed with the intra-pixel wirings 24 at different positions in the pixels in the row direction and the column direction. FIG. 26 illustrates an example in which the positions of the intra-pixel wirings 24 in the pixels are diagonally shifted from the reference wiring position of FIG. 25. FIG. 27 illustrates an example in which the positions of the intra-pixel wirings 24 in the pixels are shifted from the reference wiring position in the row direction and the column direction.

Even if the position of the intra-pixel wiring 24 varies between the pixels 2, the reflectivity of the intra-pixel wiring 24 is not changed and thus influence on irregularities in sensitivity can be reduced.

### 5. Fifth Embodiment

In a fifth embodiment, the formation pattern of inter-pixel wirings 25 is partially changed.

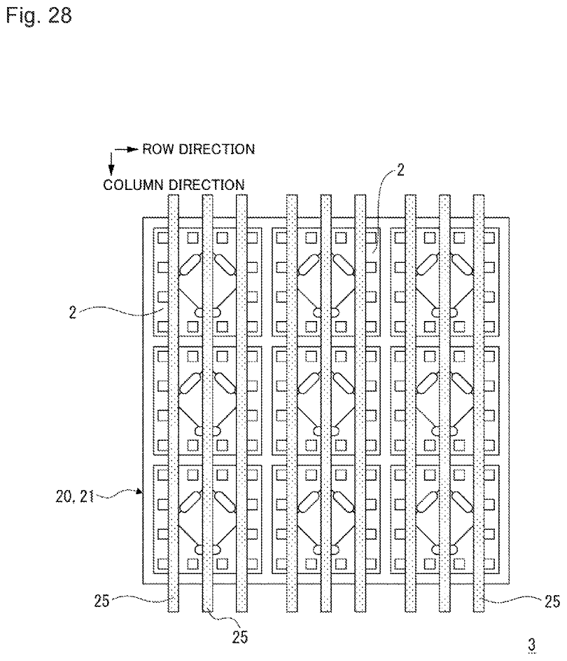

The plan view of FIG. 28 is an explanatory drawing of the inter-pixel wirings 25.

The inter-pixel wirings 25 are wirings formed to extend in one of the column direction and the row direction and cross a plurality of pixels 2 disposed in the one direction. The example of FIG. 28 illustrates the inter-pixel wirings 25 formed to extend in the column direction and cross the plurality of pixels 2 disposed in the column direction.

In a pixel array part 3, at least one inter-pixel wiring 25 is disposed in each of the pixels 2 in the other of the column direction and the row direction. Specifically, in the example of FIG. 28, the inter-pixel wirings 25 (three in FIG. 28) are disposed in each of the pixels 2 in the row direction.

Examples of the inter-pixel wirings 25 that extend in the column direction and are disposed in each of the pixels 2 in the row direction include the above-mentioned vertical signal line 9 and GND (ground) wiring.

The inter-pixel wirings 25 are typically formed with a uniform pattern in each of the pixels 2, exhibiting high periodicity.

Thus, in the fifth embodiment, at least two kinds of pixels 2 are disposed with the inter-pixel wirings 25 formed with different patterns in the array direction (the row direction in the example of FIG. 28) of the inter-pixel wirings 25, thereby reducing the periodicity. Specifically, the patterns of the inter-pixel wirings 25 vary in width or interval.

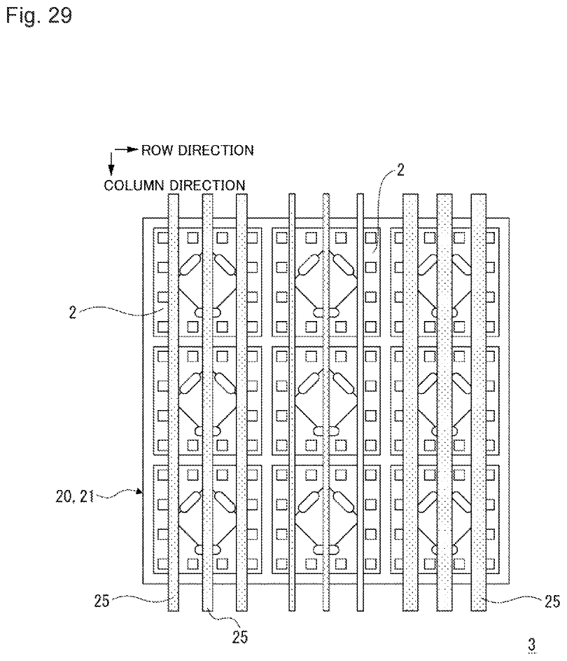

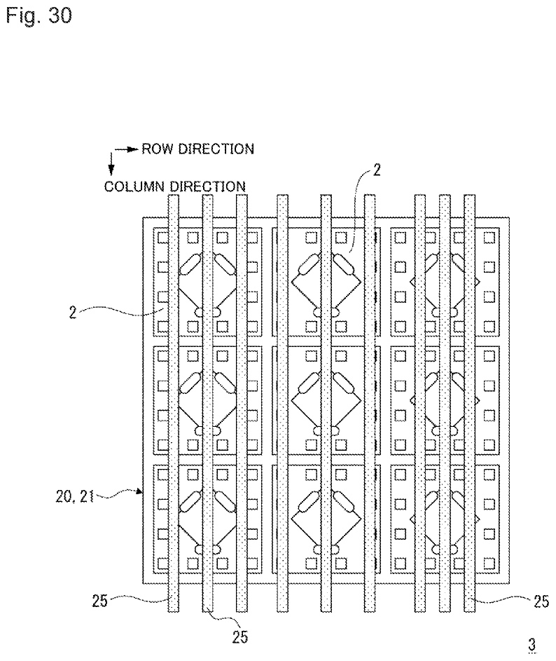

The plan views of FIGS. 29 and 30 illustrate specific examples of the fifth embodiment.

In the example of FIG. 29, the patterns of the inter-pixel wirings 25 vary in width.

Specifically, in FIG. 29, three kinds of pixels 2 are disposed with the inter-pixel wirings 25 formed with different width patterns in the row direction, which is the array direction of the inter-pixel wirings 25.

In the example of FIG. 29, the inter-pixel wirings 25 are all identical in width in one column of the pixels. The inter-pixel wirings 25 may have different widths in the column of the pixels.

In the example of FIG. 30, the width patterns of the inter-pixel wirings 25 vary in interval. Specifically, in FIG. 30, three kinds of pixels 2 are disposed with the inter-pixel wirings 25 formed with different interval patterns in the row direction, which is the array direction of the inter-pixel wirings 25.

In the example of FIG. 30, the inter-pixel wirings 25 are all identical in interval in one column of the pixels on the assumption that the three or more inter-pixel wirings 25 are disposed in one column of the pixels. The inter-pixel wirings 25 may be disposed at different intervals in the pixel 2.

The method of varying the width patterns of the inter-pixel wirings 25 in FIG. 29 and the method of varying the intervals of the inter-pixel wirings 25 in FIG. 30 may be combined.

In this configuration, the inter-pixel wirings 25 are formed in a wiring layer 12. Thus, even if the formation pattern of the inter-pixel wirings 25 varies between the pixels 2, the amount of incident light on photodiodes PD is hardly affected and thus influence on irregularities in sensitivity can be reduced.

### 6. Sixth Embodiment

In a sixth embodiment, at least two kinds of pixels 2 are disposed with different orientations in a pixel array plane in one of the row direction and the column direction.

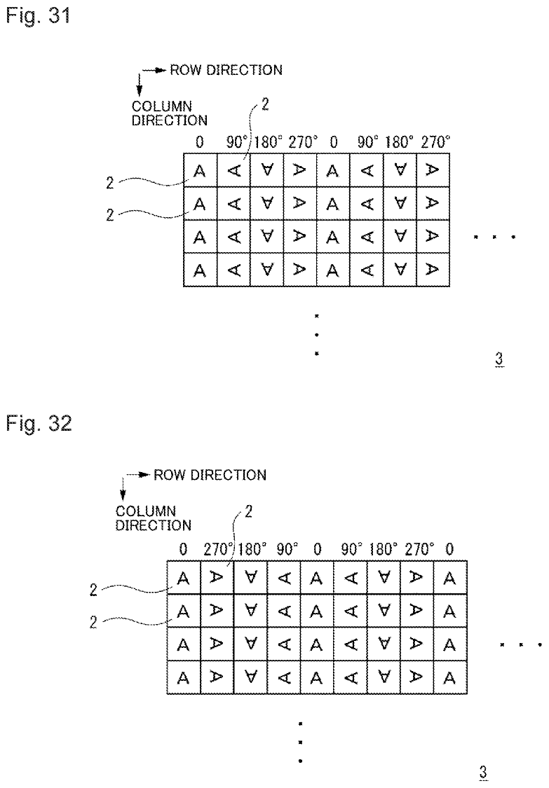

The plan views of FIGS. 31 to 34 illustrate specific examples.

In FIGS. 31 to 34, the orientations of an alphabet “A” indicate the orientations of the pixels 2 in the pixel array plane. The pixel array plane means a plane having an array of the pixels 2 and corresponds to an X-Y plane when the row direction is the X direction and the column direction is the Y direction.

Hereinafter, the orientations of the pixels 2 in the pixel array plane may be simply denoted as “orientations”.

In the examples of FIGS. 31 to 34, four angles of “0°”, “90°”, “180°”, and “270” are combined as the orientations of the pixels 2. Regarding the angles indicating the orientations of the pixels 2, a predetermined orientation of the pixel 2 is defined as “0°”, and “90°”, “180°”, and “270” are defined counterclockwise.

FIG. 31 illustrates an example in which the orientations of the pixels 2 are repeatedly changed in columns. As shown in FIG. 31, the orientations of the pixels 2 are repeatedly changed in the order of “0°”, “90°”, “180°”, and “270°” in the row direction.

FIG. 32 illustrates an example in which the orientations of the pixels 2 are changed in columns such that the columns including the pixels 2 in different orientations are disposed with line symmetry in the row direction. Specifically, in the example of FIG. 32, the columns of “90°”, the columns of “180°”, and the columns of “270°” are disposed with line symmetry with respect to the column of “0°” at the center in the row direction of FIG. 32.

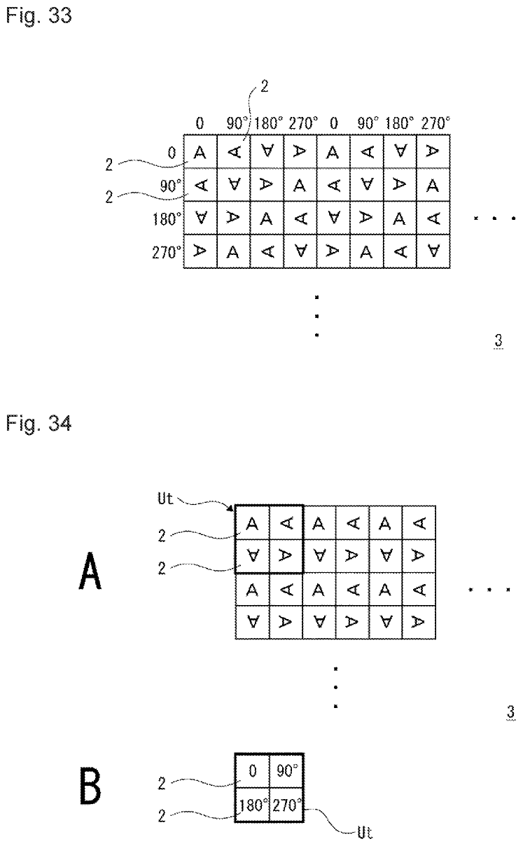

FIG. 33 illustrates an example in which the orientations of the pixels 2 are repeatedly changed in the row direction and the column direction. Specifically, the example of FIG. 33 satisfies two conditions:

Condition i) The orientations of the pixels 2 are repeatedly changed such that the pixel 2 of “0°” is followed by the pixel 2 of “90°”, the pixel 2 of “90°” is followed by the pixel 2 of “180°”, the pixel 2 of “180°” is followed by the pixel 2 of “270°”, and the pixel 2 of “270°” is followed by the pixel 2 of “0°” in each row.

Condition ii) The orientations of the pixels 2 are repeatedly changed such that the pixel 2 of “0°” is followed by the pixel 2 of “90°”, the pixel 2 of “90°” is followed by the pixel 2 of “180°”, the pixel 2 of “180°” is followed by the pixel 2 of “270°”, and the pixel 2 of “270°” is followed by the pixel 2 of “0°” in each column.

FIG. 34 illustrates an example in which units Ut are disposed in the row direction and the column direction, the unit Ut including the pixels 2 in different orientations. It is assumed that the unit Ut is, as illustrated in FIG. 34B, a combination of the four pixels 2 in the orientations of “0°”, “90°”, “180°”, and “270°”. As illustrated in FIG. 34A, the units Ut are disposed in the row direction and the column direction.

As described above, the pixels 2 in different orientations can partially reduce the periodicity of the pattern of a fine structure in a pixel array part 3, thereby suppressing a flare.

### 7. Modification Example

The embodiment is not limited to the specific examples described above, and configurations as various modification examples can be adopted.

For example, some or all of the methods for suppressing a flare according to the first to sixth embodiments can be combined. For example, the method of partially changing the formation pattern of the inter-pixel isolating portion 20 or the inter-pixel light-shielding portion 21 according to the first embodiment and the method of partially changing the layout of the intra-pixel wirings 24 in the pixels according to the fourth embodiment may be combined.

Alternatively, the method of partially changing the formation pattern of the inter-pixel isolating portion 20 or the inter-pixel light-shielding portion 21 according to the first embodiment, the method of partially changing the layout of the polysilicon portion 23 in the pixels according to the third embodiment, and the method of partially changing the formation pattern of the inter-pixel wirings 25 according to the fifth embodiment may be combined. In addition, the methods for suppressing a flare according to the first to sixth embodiments can be optionally combined.

In the foregoing example, the present technique is applied to an image sensor, that is, a sensor device that obtains an image indicating the amount of received light for each of the pixels 2 as a sensing image. The present technique is also properly applicable to a depth sensor, for example, a ToF (Time of Flight) sensor that obtains a depth image (an image indicating a distance for each of the pixels 2) as a sensing image.

For example, in the case of a depth sensor for iToF(indirect ToF), one photodiode PD in each of the pixels is provided with the floating diffusions FD as many as multiples of 2 and the transfer transistors Qt as many as the floating diffusions FD. By sequentially turning on/off the transfer transistors Qt, the accumulated charges of the photodiodes PD are sequentially transferred to the floating diffusions FD.

A ToF sensor may be adopted without the microlenses 17. In this case, a flare cannot be suppressed by the method disclosed in PTL 1. In this respect, the method of suppressing a flare according to the present technique is suitable for a ToF sensor.

### 8. Summary of Embodiments

As described above, a first sensor device (sensor device 1) as an embodiment includes an array of a plurality of pixels (pixels 2) in the row direction and the column direction, the pixel including a photoelectric conversion element (photodiode PD), wherein at least two kinds of pixels are disposed with an inter-pixel isolating structure (inter-pixel isolating portion 20) formed with a different pattern in one of the row direction and the column direction (see the first embodiment).

Thus, when a flare is suppressed by partially reducing the periodicity of the pattern of a fine structure, the need for an additional manufacturing step can be eliminated.

This can suppress a flare while preventing the manufacturing process of the sensor device from becoming complicated.

In the first sensor device as the embodiment, the at least two kinds of pixels have different width patterns on the end face of the inter-pixel isolating structure near the light entrance surface.

The width of the inter-pixel isolating structure can be easily set by setting a mask pattern when the inter-pixel isolating structure is formed.

This can improve the ease of manufacturing of the sensor device while suppressing a flare.

In the first sensor device as the embodiment, the end face of the inter-pixel isolating structure has an equal area in the at least two kinds of pixels.

Thus, for the at least two kinds of pixels with the inter-pixel isolating structure formed with different patterns, an equal amount of incident light can be obtained in each of the pixels. This can suppress a flare and reduce irregularities in sensitivity.

Furthermore, in the first sensor device as the embodiment, the inter-pixel isolating structure in each of the at least two kinds of pixels has, as a width on the end face, a first width portion (first width portion 20a) having a first width and a second width portion (second width portion 20b) having a second width larger than the first width, and the total length of the second width portions in the inter-pixel isolating structure is equal in the at least two kinds of pixels.

Thus, for the at least two kinds of pixels, when the inter-pixel isolating structure has an equal end face area near the light entrance surface to obtain an equal amount of incident light in each of the pixels, at least two widths can be combined as a width pattern of the inter-pixel isolating structure, thereby eliminating the need for a complicated change of the width.

This can prevent the shape of the inter-pixel isolating structure from being complicated, thereby improving the ease of manufacturing of the sensor device so as to reduce the manufacturing cost.

A second sensor device as an embodiment includes an array of a plurality of pixels (pixels 2) in the row direction and the column direction, the pixel including a photoelectric conversion element (photodiode PD), wherein at least two kinds of pixels are disposed with an inter-pixel light-shielding structure (inter-pixel light-shielding portion 21) formed with a different pattern in one of the row direction and the column direction (see the first embodiment).

Thus, when a flare is suppressed by partially reducing the periodicity of the pattern of a fine structure, the need for an additional manufacturing step can be eliminated. This can suppress a flare while preventing the manufacturing process of the sensor device from becoming complicated.

In the second sensor device as the embodiment, the at least two kinds of pixels have different width patterns on the end face of the inter-pixel light-shielding structure near the light entrance surface.

The width of the inter-pixel light-shielding structure can be easily set by setting a mask pattern when the inter-pixel light-shielding structure is formed.

This can improve the ease of manufacturing of the sensor device while suppressing a flare.

In the second sensor device as the embodiment, the end face of the inter-pixel light-shielding structure has an equal area in the at least two kinds of pixels.

Thus, for the at least two kinds of pixels with the inter-pixel light-shielding structure formed with different patterns, an equal amount of incident light can be obtained in each of the pixels. This can suppress a flare and reduce irregularities in sensitivity.

Furthermore, in the second sensor device as the embodiment, the inter-pixel light-shielding structure in each of the at least two kinds of pixels has, as a width on the end face, a first width portion (first width portion 21a) having a first width and a second width portion (second width portion 21b) having a second width larger than the first width, and the total length of the second width portions in the inter-pixel light-shielding structure is equal in the at least two kinds of pixels.

Thus, for the at least two kinds of pixels, when the inter-pixel light-shielding structure has an equal end face area near the light entrance surface to obtain an equal amount of incident light in each of the pixels, at least two widths can be combined as a width pattern of the inter-pixel light-shielding structure, thereby eliminating the need for a complicated change of the width. This can prevent the shape of the inter-pixel light-shielding structure from being complicated, thereby improving the ease of manufacturing of the sensor device so as to reduce the manufacturing cost.

The first or second sensor device as the embodiment includes at least two kinds of pixels disposed with an intra-pixel isolating structure (intra-pixel isolating portion 22) formed with a different pattern in one of the row direction and the column direction (see the second embodiment).

The intra-pixel isolating structure formed with a different pattern can partially reduce the periodicity of the pattern of a fine structure. Furthermore, when the intra-pixel isolating structure is formed with a different pattern, the need for an additional manufacturing step can be eliminated.

This can suppress a flare while preventing the manufacturing process of the sensor device from becoming complicated.

In the first or second sensor device as the embodiment, the at least two kinds of pixels with the intra-pixel isolating structure formed with different patterns have different width patterns on the end face of the intra-pixel isolating structure near the light entrance surface.

The width of the intra-pixel isolating structure can be easily set by setting a mask pattern when the intra-pixel isolating structure is formed.

This can improve the ease of manufacturing of the sensor device that suppresses a flare.

The first or second sensor device as the embodiment includes the wiring layer (wiring layer 12) stacked on the semiconductor substrate (semiconductor substate 11) in which photoelectric conversion elements are formed, wherein the at least two kinds of pixels are disposed with polysilicon portions (polysilicon portions 23) that are formed in the wiring layer and located at different positions in the pixels in one of the row direction and the column direction (see the third embodiment).

The polysilicon portions formed in the wiring layer are located at different positions in the pixels, so that the periodicity of the pattern of the fine structure can be partially reduced. Furthermore, when the polysilicon portions are located at different positions in the pixels, the need for an additional manufacturing step can be eliminated.

This can suppress a flare while preventing the manufacturing process of the sensor device from becoming complicated.

The first or second sensor device as the embodiment includes the wiring layer stacked on the semiconductor substrate in which photoelectric conversion elements are formed, wherein the at least two kinds of pixels are disposed with the intra-pixel wirings (intra-pixel wirings 24) that are formed in the wiring layer and located at different positions in the pixels in one of the row direction and the column direction (see the fourth embodiment).

The intra-pixel wirings are located at different positions in the pixels, so that the periodicity of the pattern of the fine structure can be partially reduced. Furthermore, when the intra-pixel wirings are located at different positions in the pixels, the need for an additional manufacturing step can be eliminated.

This can suppress a flare while preventing the manufacturing process of the sensor device from becoming complicated.

The first or second sensor device as the embodiment includes the inter-pixel wirings (the inter-pixel wirings 25) formed to extend in one of the column direction and the row direction and cross the plurality of pixels disposed in the one direction, the inter-pixel wirings being disposed for each of the pixels in the other direction of the column direction and the row direction, wherein the at least two kinds of pixels are disposed with the inter-pixel wirings formed with different patterns in the other direction (see the fifth embodiment). The inter-pixel wirings disposed for each of the pixels are formed with different patterns, thereby partially reducing the periodicity of the pattern of the fine structure. Furthermore, when the inter-pixel wirings are formed with different patterns, the need for an additional manufacturing step can be eliminated.

This can suppress a flare while preventing the manufacturing process of the sensor device from becoming complicated.

In the first or second sensor device as the embodiment, the at least two kinds of pixels have the inter-pixel wirings formed with different patterns such that the patterns of the inter-pixel wirings vary in width or interval.

The widths and intervals of the inter-pixel wirings can be easily set by setting a mask pattern when the inter-pixel wirings are formed.

This can improve the ease of manufacturing of the sensor device while suppressing a flare.

In the first or second sensor device as the embodiment, the at least two kinds of pixels are disposed with different orientations in a pixel array plane in one of the row direction and the column direction (see the sixth embodiment).

The pixels disposed with different orientations in the pixel array plane can partially reduce the periodicity of the pattern of the fine structure. Furthermore, when the pixels are disposed with different orientations, the need for an additional manufacturing step can be eliminated.

This can suppress a flare while preventing the manufacturing process of the sensor device from becoming complicated.

Note that the advantageous effects described in the present specification are merely exemplary and are not limited, and other advantageous effects may be obtained.

### 9. Present Technique

The present technique can be also configured as follows:

(1) A sensor device including an array of a plurality of pixels in a row direction and a column direction, each of the pixels including a photoelectric conversion element,

wherein at least two kinds of pixels are disposed with an inter-pixel isolating structure formed with a different pattern in one of the row direction and the column direction.

(2) The sensor device according to (1), wherein the at least two kinds of pixels have different width patterns on the end face of the inter-pixel isolating structure near the light entrance surface.

(3) The sensor device according to (2), wherein the end face of the inter-pixel isolating structure has an equal area in the at least two kinds of pixels.

(4) The sensor device according to (3), wherein the inter-pixel isolating structure in each of the at least two kinds of pixels has, as a width on the end face, a first width portion having a first width and a second width portion having a second width larger than the first width, and the total length of the second width portions in the inter-pixel isolating structure is equal in the at least two kinds of pixels.

(5) A sensor device including an array of a plurality of pixels in a row direction and a column direction, each of the pixels including a photoelectric conversion element, wherein at least two kinds of pixels are disposed with an inter-pixel light-shielding structure formed with a different pattern in one of the row direction and the column direction.

(6) The sensor device according to (5), wherein the at least two kinds of pixels have different width patterns on the end face of the inter-pixel light-shielding structure near the light entrance surface.

(7) The sensor device according to (6), wherein the end face of the inter-pixel light-shielding structure has an equal area in the at least two kinds of pixels.

(8) The sensor device according to (7), wherein the inter-pixel light-shielding structure in each of the at least two kinds of pixels has, as a width on the end face, a first width portion having a first width and a second width portion having a second width larger than the first width, and

the total length of the second width portions in the inter-pixel light-shielding structure is equal in the at least two kinds of pixels.

(9) The sensor device according to any one of (1) to (8), wherein the at least two kinds of pixels are disposed with the intra-pixel isolating structure formed with a different pattern in one of the row direction and the column direction.

(10) The sensor device according to (9), wherein the at least two kinds of pixels with the intra-pixel isolating structure formed with different patterns have different width patterns on the end face of the intra-pixel isolating structure near the light entrance surface.

(11) The sensor device according to any one of (1) to (10), further comprising a wiring layer stacked on a semiconductor substrate in which the photoelectric conversion elements are formed,

wherein the at least two kinds of pixels are disposed with polysilicon portions that are formed in the wiring layer and located at different positions in the pixels in one of the row direction and the column direction.

(12) The sensor device according to any one of (1) to (10), further comprising a wiring layer stacked on a semiconductor substrate in which the photoelectric conversion elements are formed,

wherein the at least two kinds of pixels are disposed with intra-pixel wirings that are formed in the wiring layer and located at different positions in the pixels in one of the row direction and the column direction.

(13) The sensor device according to any one of (1) to (12) includes inter-pixel wirings formed to extend in one of the column direction and the row direction and cross the plurality of pixels disposed in the one direction, the inter-pixel wirings being disposed for each of the pixels in the other direction of the column direction and the row direction,

wherein the at least two kinds of pixels are disposed with the inter-pixel wirings formed with different patterns in the other direction.

(14) The sensor device according to (13), wherein the at least two kinds of pixels have the inter-pixel wirings formed with different patterns such that the patterns of the inter-pixel wirings vary in width or interval.

(15) The sensor device according to any one of (1) to (14), wherein the at least two kinds of pixels are disposed with different orientations in a pixel array plane in one of the row direction and the column direction.

### REFERENCE SIGNS LIST

1 Sensor device
2 Pixel
3 Pixel array part
PD Photodiode
FD Floating diffusion
Qt Transfer transistor
Qr Reset transistor
Qa Amplifying transistor
Qs Selecting transistor
TG Transfer driving signal
RST Reset signal
SLC Selecting signal
11 Semiconductor substrate
12 Wiring layer
12a Wiring
12b Interlayer insulating film
13 Fixed charge film
14 Insulating film
15 Flattening film
16 Filter layer
17 Microlens
20 Inter-pixel isolating portion
20a First width portion
20b Second width portion
20c Third width portion
20d Fourth width portion
21 Inter-pixel light-shielding portion
21a First width portion
21b Second width portion
21c Third width portion
21d Fourth width portion
22 Intra-pixel isolating portion
23 Polysilicon portion
24 Intra-pixel wiring
25 Inter-pixel wiring

What is claimed is:

1. A sensor device comprising an array of a plurality of pixels in a row direction and a column direction, each of the pixels including a photoelectric conversion element,
wherein at least two kinds of pixels are disposed with an inter-pixel isolating structure formed with a different pattern in one of the row direction and the column direction.

2. The sensor device according to claim 1, wherein the at least two kinds of pixels have different width patterns on an end face of the inter-pixel isolating structure near a light entrance surface.

3. The sensor device according to claim 2, wherein the end face of the inter-pixel isolating structure has an equal area in the at least two kinds of pixels.

4. The sensor device according to claim 3, wherein the inter-pixel isolating structure in each of the at least two kinds of pixels has, as a width on the end face, a first width portion having a first width and a second width portion having a second width larger than the first width, and
a total length of the second width portions in the inter-pixel isolating structure is equal in the at least two kinds of pixels.

5. A sensor device comprising an array of a plurality of pixels in a row direction and a column direction, each of the pixels including a photoelectric conversion element,
wherein at least two kinds of pixels are disposed with an inter-pixel light-shielding structure formed with a different pattern in one of the row direction and the column direction.

6. The sensor device according to claim 5, wherein the at least two kinds of pixels have different width patterns on an end face of the inter-pixel light-shielding structure near a light entrance surface.

7. The sensor device according to claim 6, wherein the end face of the inter-pixel light-shielding structure has an equal area in the at least two kinds of pixels.

8. The sensor device according to claim 7, wherein the inter-pixel light-shielding structure in each of the at least two kinds of pixels has, as a width on the end face, a first width portion having a first width and a second width portion having a second width larger than the first width, and
a total length of the second width portions in the inter-pixel light-shielding structure is equal in the at least two kinds of pixels.

9. The sensor device according to claim 1, wherein the at least two kinds of pixels are disposed with the intra-pixel isolating structure formed with a different pattern in one of the row direction and the column direction.

10. The sensor device according to claim 9, wherein the at least two kinds of pixels with the intra-pixel isolating structure formed with different patterns have different width patterns on an end face of the intra-pixel isolating structure near a light entrance surface.

11. The sensor device according to claim 1, further comprising a wiring layer stacked on a semiconductor substrate in which the photoelectric conversion elements are formed,
wherein the at least two kinds of pixels are disposed with polysilicon portions that are formed in the wiring layer and located at different positions in the pixels in one of the row direction and the column direction.

12. The sensor device according to claim 1, further comprising a wiring layer stacked on a semiconductor substrate in which the photoelectric conversion elements are formed,
wherein the at least two kinds of pixels are disposed with intra-pixel wirings that are formed in the wiring layer and located at different positions in the pixels in one of the row direction and the column direction.

13. The sensor device according to claim 1, further comprising inter-pixel wirings formed to extend in one of the column direction and the row direction and cross the plurality of pixels disposed in the one direction, the inter-pixel wirings being disposed for each of the pixels in the other direction of the column direction and the row direction,
wherein the at least two kinds of pixels are disposed with the inter-pixel wirings formed with different patterns in the other direction.

14. The sensor device according to claim 13, wherein the at least two kinds of pixels have the inter-pixel wirings formed with different patterns such that the patterns of the inter-pixel wirings vary in width or interval.

15. The sensor device according to claim 1, wherein the at least two kinds of pixels are disposed with different orientations in a pixel array plane in one of the row direction and the column direction.
